(19) United States
(12) Patent Application Publication
(10) Pub. No.: US 2013/0273237 A1
(43) Pub. Date: Oct. 17, 2013

(54) Method to Determine the Thickness of a Thin Film During Plasma Deposition

(71) Applicant: David Johnson, Cleveland, GA (US)

(72) Inventor: David Johnson, Cleveland, GA (US)

(21) Appl. No.: 13/445,211

(22) Filed: Apr. 12, 2012

(51) Int. Cl. C23C 16/50

(52) U.S. Cl. 427/9

(57) ABSTRACT

The present invention provides a method to determine the thickness of a thin film during deposition. A target film thickness is set. A substrate is placed within a deposition system. The thin film is deposited onto the substrate within the deposition system. Radiation reflected from the substrate is monitored at multiple wavelengths during the deposition of the thin film using standard OEI techniques. A value derived from the reflected radiation is monitored. A time is detected at which the derived value is at a target value. A film thickness is calculated at the detected times to generate data. A mathematical analysis is performed on the generated data to determine an equation for deposited film thickness versus time. The calculated equation for deposited film thickness versus time is used to achieve the target film thickness.

### FIELD OF THE INVENTION

The present invention relates to a method for measuring the thickness of a thin film and in particular to a method for measuring in situ the thickness of a thin film deposited using a Plasma Enhanced Chemical Vapor Deposition (PECVD) technique and measuring the plasma emission at multiple wavelengths.

### BACKGROUND OF THE INVENTION

Thin films of dielectric materials, semiconducting materials and conducting materials are extensively used in the manufacture of semiconductor devices. Such films are typically deposited on a substrate such as silicon or gallium arsenide, and subsequently patterned to produce and interconnect devices such as transistors, capacitors, diodes and the like. Discrete devices such as light emitting diodes are similarly fabricated. Deposition is performed using a variety of techniques including Physical Vapor Deposition (PVD), Chemical Vapor Deposition (CVD), Atomic Layer Deposition (ALD) and the like, and plasma enhanced techniques such as PECVD and High Density PECVD (HDPECVD). Deposition using plasma processing in a vacuum system is well known (PECVD and HDPECVD) as is also plasma etching which is used as a means of etching and defining patterns in the film.

The thickness of these deposited films is a parameter which is carefully controlled since it determines the operation of the device within its design limits. The control must be done over an extended period of time and also from machine to machine, since all films will not be deposited on one piece of equipment. Thus, there are numerous techniques which have been developed in order to accurately measure the thickness of the film. For films which are transparent, such as many dielectrics (which include silicon dioxide, silicon nitride and polymeric materials), semiconductors (such as thin films of gallium nitride) and some conductors (such as indium tin oxide), optical techniques can be used to measure the film thickness. Ellipsometry is used to measure film thickness based on the interaction of the film with polarized light, and reflectance measurements are used to determine film thickness based on comparison of the measured reflectance spectrum with a theoretical model of the reflectance spectrum. Both techniques are used primarily post-processing as a means to verify that the deposited film thickness is within the desired range, or to initiate corrective measures if the film thickness is outside of the desired range.

A more desirable thickness measurement is one made during the processing step, so that the process can be terminated when the desired film thickness has been achieved. Thus it is possible to compensate for any long or short term variations in the process or machine to machine variations by adjusting the process time. Such “endpoint” techniques are commonly used for many etch processes where a film is completely removed. The removal of the film can be detected, for example, by monitoring the change in the plasma emission which occurs when the film is no longer being etched. In order to obtain information about the thickness of a film as it is deposited, reflectance measurements can be made in situ by measuring the intensity of a light source after reflection from the film surface. The light source may be an external one, such as a laser or a broadband light source, or an internal one, that is the plasma emission itself, in which case the technique is referred to as Optical Emission Interferometry (OEI) or some combination of internal and external sources. For example, during the deposition of silicon nitride, the emission of molecular Nitrogen in the region 300 nm to 400 nm reflected from the substrate surface can be effectively used. The reflection is ideally measured at an angle close to normal incidence to the film surface, which requires a particular arrangement of the viewing optics, in particular the vacuum viewport. The optics must be arranged so that there is no local disturbance of the process and also so that there is no degradation due to exposure to the plasma. Such an arrangement for an etch system is described by Sawin (U.S. Pat. No. 5,450,205) and for a deposition system by Johnson (U.S. Pat. No. 7,833,381), where the reflectance is monitored through a hole in the gas introduction showerhead.

When the reflectance is measured at a single wavelength, the intensity of the signal will vary in a sinusoidal manner due to interference effects within the film as the film thickness changes. (FIG. 1a) The change in film thickness, d, which results in a complete cycle of the interference signal is given by EQUATION 1:

d=λ/2*n_{f}

where: λ=wavelength at which reflectance is monitored

n_{f}=refractive index of film at this wavelength

Thus by counting maxima (and minima) in the interference signal and also interpolating between them, it is possible to calculate the change in film thickness versus time and terminate the process when the desired thickness change has occurred (FIGS. 1a, 1b). Since the change in thickness, d, is directly proportional to the wavelength, λ, it is beneficial to measure the reflectance at short wavelengths, for example below 400 nm, as this will provide an improvement in the thickness measurement resolution. For less critical applications where such resolution is not required, longer wavelengths may be employed. Note that the choice of appropriate wavelengths is a function of the wavelengths available from the light source(s) as well as the optical properties of the material to be measured. Reflectance measurements can thus be used to accurately measure the thickness of films which generate multiple interference cycles during the deposition process. An estimate of the deposition rate can be recalculated each time a signal extrema (maximum or minimum) is detected and by averaging these multiple measurements, or otherwise using statistical means to better approximate the true deposition rate, it is possible to deposit a film within a few percent of the target thickness.

However, there are some devices (e.g., some thin film capacitors) for which a very thin layer of dielectric is required. The design thickness for such a film may be of the order of less than 100 nm to less than a few 10's of nm. To ensure consistent device performance the requirement for film thickness reproducibility is of the order of 1% which means the target thickness must be met within an approximate range of <1 nm, preferably <0.5 nm. For such very thin films, multiple interference cycles are typically not generated during the deposition process. For example, during the deposition of a silicon nitride film with a refractive index of 2.0 and a measurement wavelength of 337 nm, a complete cycle is only generated for a thickness of approximately 84 nm. Hence for films equal to or less than this thickness, the improved accuracy obtained by the averaging of multiple measurements cannot be achieved. Making a single measurement (e.g., the time of the first interference minimum), using this value to calculate a deposition rate and then extrapolating to calculate the desired process termination time, is prone to significant error, since this approach inherently assumes a linear response of deposition thickness versus time. This is typically not the case, since the deposition rate may be anomalously high or low during the first few seconds of the process, which time represents a significant fraction of the process time for the deposition of such a thin film. The instability can be due to multiple factors, such as the time required for the plasma to stabilize as the RF power is applied.

Monitoring the interference at multiple wavelengths provides additional data which can be used to calculate a more reliable value for the deposition rate. (see U.S. Pat. No. 6,888,639). However, the method described in U.S. Pat. No. 6,888,639 relies on “cycle counting” and a linear film thickness versus time response. This is appropriate for films generating multiple interference cycles, but does not teach how to apply multiple wavelength measurements to the measurement of thin films where a complete interference cycle is not generated.

Likewise, using OEI at multiple wavelengths is described in U.S. Pat. No. 7,833,381, but no method is taught on how such measurements can be used to determine the thickness of thin films where a complete interference cycle is not generated.

Thus, none of the prior art teaches how to calculate the thickness of a thin film where a complete interference cycle is not generated, with the desired degree of accuracy using multi-wavelengths.

None of the methods describe how to overcome such interference limitations for thin films.

Nothing in the prior art provides the benefits attendant with the present invention.

Therefore, it is an object of the present invention to provide an improvement which overcomes the inadequacies of the prior art methods and which is a significant contribution to the advancement to the processing of semiconductor substrates using OEI to accurately measure the thickness of thin films deposited in a plasma processing system.

Another object of the present invention is to provide a method to determine the thickness of a thin film during deposition, said method comprising the steps of: setting a target film thickness; placing a substrate within a deposition system; depositing the thin film onto the substrate within the deposition system; monitoring radiation reflected from the substrate at multiple wavelengths during the deposition of the thin film; monitoring a value derived from the reflected radiation; detecting a time at which the derived value achieves a target value; calculating a film thickness at the detected times to generate data; performing a mathematical analysis on the generated data to determine an equation for deposited film thickness versus time; and using the determined equation for deposited film thickness versus time to obtain an estimated time to achieve the target film thickness.

Still yet another object of the present invention is to provide a method to determine the thickness of a thin film during plasma deposition, said method comprising the steps of: setting a target film thickness; placing a substrate within a plasma deposition system; introducing a reactive gas into the plasma deposition system; igniting a plasma from the reactive gas within the plasma deposition system; depositing the thin film from the ignited plasma onto the substrate within the plasma deposition system; monitoring plasma emitted radiation reflected from the substrate at multiple wavelengths during the deposition of the thin film; monitoring a value derived from the reflected plasma radiation; detecting a time at which the derived value achieves a target value; calculating a film thickness at the detected times to generate data; performing a mathematical analysis on the generated data to determine an equation for deposited film thickness versus time; and using the determined equation for deposited film thickness versus time to obtain an estimated time to achieve the target film thickness.

Another object of the present invention is to provide a method to determine the thickness of a thin film during deposition, said method comprising the steps of: setting initial values for refractive index using at least two wavelengths; setting a target film thickness; placing a substrate within a deposition system; depositing the thin film onto the substrate within the deposition system; monitoring intensity versus time at the at least two wavelengths during the deposition of the thin film; terminating the process when the target film thickness is achieved; measuring the film thickness; calculating the refractive index at the at least two wavelengths using the measured film thickness; updating the initial values of refractive index for the at least two wavelengths; and processing the next substrate using the updated initial values of refractive index for the at least two wavelengths.

The foregoing has outlined some of the pertinent objects of the present invention. These objects should be construed to be merely illustrative of some of the more prominent features and applications of the intended invention. Many other beneficial results can be attained by applying the disclosed invention in a different manner or modifying the invention within the scope of the disclosure. Accordingly, other objects and a fuller understanding of the invention may be had by referring to the summary of the invention and the detailed description of the preferred embodiment in addition to the scope of the invention defined by the claims taken in conjunction with the accompanying drawings.

### SUMMARY OF THE INVENTION

The present invention is a method of measuring multiple wavelengths through OEI to calculate the thickness of a thin film in real time during the deposition of the thin film in a plasma processing chamber.

A feature of the present invention is to provide a method to determine the thickness of a thin film during deposition. The method comprising the steps of setting a target film thickness for the deposition of the thin film. A substrate is placed within a deposition system. The thin film is deposited onto the substrate within the deposition system. Reflected radiation from the substrate is monitored at multiple wavelengths during the deposition of the thin film. The monitoring can be accomplished using standard OEI techniques. The multiple wavelengths used for monitoring can be between 290 nm to 420 nm or be the wavelengths emitted by molecular Nitrogen. A value derived from the reflected radiation is monitored during the deposition. A time is detected at which the derived value achieves a target value. A film thickness is calculated at each of the detected times to generate data. A mathematical analysis (such as a regression analysis) is performed on the generated data to determine an equation for deposited film thickness versus time. The regression analysis can use a linear fit or a polynomial fit. The determined equation for deposited film thickness versus time is used to obtain an estimated time to achieve the target film thickness of the deposition. The deposition of the thin film can be terminated when the estimated time achieves the target film thickness. The deposition of the thin film can be changed when the estimated time achieves the target film thickness.

Yet another feature of the present invention is to provide a method to determine the thickness of a thin film during plasma deposition. The method comprising the steps of setting a target film thickness for the plasma deposition of the thin film. A substrate is placed within a plasma deposition system. A reactive gas is introduced into the plasma deposition system. A plasma is ignited from the reactive gas within the plasma deposition system. The thin film is deposited from the ignited plasma onto the substrate within the plasma deposition system. Plasma emitted radiation reflected from the substrate is monitored at multiple wavelengths during the deposition of the thin film. The monitoring can be accomplished using standard OEI techniques. The multiple wavelengths used for monitoring can be between 290 nm to 420 nm or be the wavelengths emitted by molecular Nitrogen. A value derived from the reflected radiation is monitored during the plasma deposition. A time is detected at which the derived value achieves a target value. A film thickness is calculated at each of the detected times to generate data. A mathematical analysis (such as a regression analysis) is performed on the generated data to determine an equation for deposited film thickness versus time. The regression analysis can use a linear fit or a polynomial fit. The determined equation for deposited film thickness versus time is used to obtain an estimated time to achieve the target film thickness of the plasma deposition. The plasma deposition of the thin film can be terminated when the estimated time achieves the target film thickness. The plasma deposition of the thin film can be changed when the estimated time achieves the target film thickness.

Still yet another feature of the present invention is to provide a method to determine the thickness of a thin film during deposition. The method comprising the steps of setting initial values for refractive index using at least two wavelengths that will be monitored during the deposition of the thin film. A target film thickness is set for the deposition. A substrate is placed within a deposition system. The thin film is deposited onto the substrate within the deposition system. The intensity versus time of reflected radiation at the two wavelengths having set initial values for refractive index are monitored during the deposition of the thin film. The process is terminated when the target film thickness is achieved and the film thickness is measured. The refractive index is calculated at the at least two wavelengths using the measured film thickness. The initial values of refractive index are updated for the at least two wavelengths and the next substrate is processed using the updated initial values of refractive index for the at least two wavelengths.

The foregoing has outlined rather broadly the more pertinent and important features of the present invention in order that the detailed description of the invention that follows may be better understood so that the present contribution to the art can be more fully appreciated. Additional features of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

FIG. 1a is a graph of signal versus time for multiple interference cycles as taught by the prior art;

FIG. 1b is a graph of film thickness versus time for multiple interference cycles as taught by the prior art;

FIG. 2a is a graph of signal versus time for the first minimum observed as taught by the prior art;

FIG. 2b is a graph of film thickness versus time for the first minimum observed as taught by the prior art;

FIG. 3a is a schematic enlarged view of a showerhead hole in a plasma system;

FIG. 3b is a schematic enlarged view of a showerhead assembly in a plasma system;

FIG. 4 is a graph of signal versus wavelength for the nitrogen emission during a silicon nitride and silicon dioxide plasma deposition process;

FIG. 5 is a graph of signal versus time for the first minimum in interference signal at multiple wavelengths according to the present invention;

FIG. 6 is a graph of signal versus time for false minima in interference signal;

FIG. 7 is a graph of signal versus time showing the calculated the true minima in interference signal according to the present invention;

FIG. 8 is a graph of film thickness versus time showing the calculated film thickness according to the present invention;

FIG. 9 is a graph of film thickness versus target film thickness according to the present invention;

FIG. 10 is a flow chart of the deposition process according to the present invention;

FIG. 11 is a flow chart of the refractive index determination according to the present invention;

FIG. 12 is a table of the refractive index measurement of silicon nitride film;

FIG. 13 is a table of calculated film thickness at first interference minimum according to the present invention;

FIG. 14 is a table of calculation of film thickness versus time for deposition of 50 nm of silicon nitride film according to the present invention; and

FIG. 15 is a flowchart of one of the embodiments for a method of depositing a thin film according to the present invention.

Similar reference characters refer to similar parts throughout the several views of the drawings.

### DETAILED DESCRIPTION OF THE INVENTION

The present invention provides a means of measuring in situ the thickness of a film deposited in a deposition system, such as a PVD, CVD, or ALD system and the like, and in particular in a plasma deposition system (PECVD or HDPECVD). Such apparatus is well known in the semiconductor industry, and typically comprises a vacuum chamber including a heated substrate support on which a substrate is placed, a means of introducing process gases into the chamber, a power supply or multiple power supplies such as a 13.56 MHz RF supply to generate a plasma, and a means of pumping the reacted gases from the vacuum chamber. Typical of such equipment is the Versaline PECVD supplied by Plasma Therm, LLC, though other similar equipment may be suitable. Additionally, the technique allows for the measurement of thin films, such as polymeric films, which may be deposited, for example, in a plasma etch system as part of an etch process.

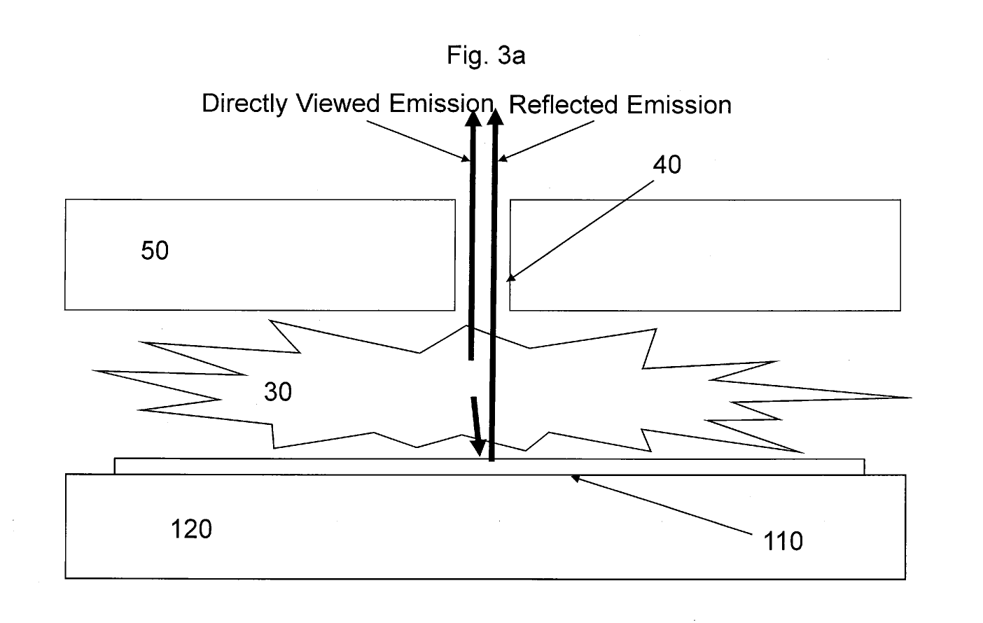

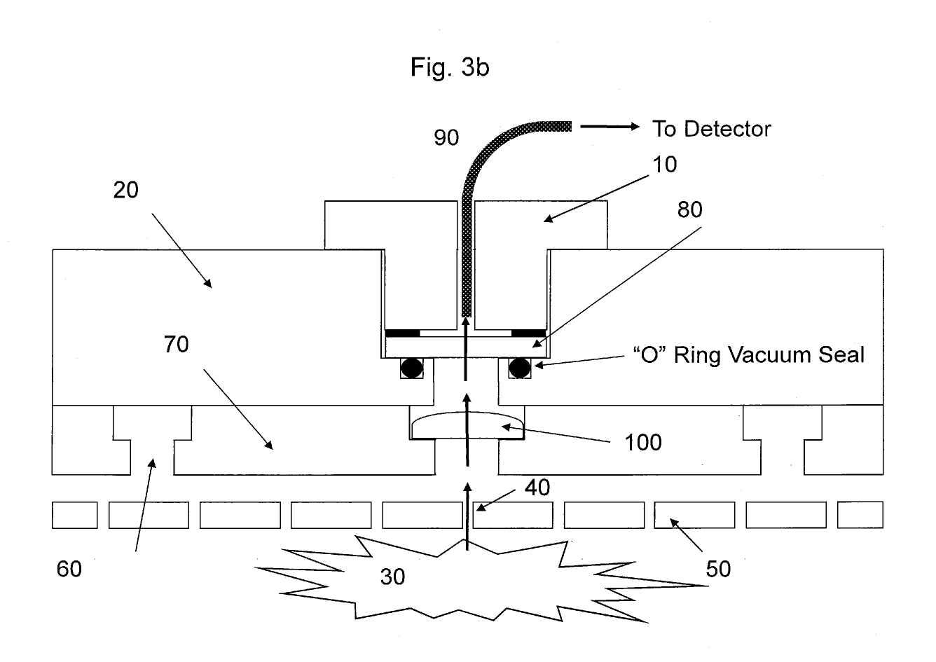

In order to monitor the reflection from the substrate surface a viewport is located at a point above the substrate and the reflected light led to a detector, most conveniently using a fiber optic cable. The light source necessary for the reflectance measurement may be an external one such as a laser, or broadband, for example a xenon arc lamp, or an internal light source, that is the plasma emission itself may be used, i.e., OEI. Alternatively, some combination of external and internal light sources may be used. The OEI approach provides distinct advantages since there is no requirement for additional components, including an external light source and power supply, and focusing and alignment optics, which greatly simplifies the practical implementation of the technique. The detector can be a spectrometer which disperses the emitted radiation and permits detection of a wide range of wavelengths, or can be, for example, an array of discrete wavelength filters and individual detectors. A suitable arrangement used to obtain OEI measurements is shown in FIGS. 3a, 3b (after Johnson, U.S. Pat. No. 7,833,381). Emission from the plasma (30) is reflected normally from the substrate (110) and passes through a showerhead hole (40) located in the gas introduction showerhead (50). A lens (100) focuses the emission through the viewport (80) to a fiber optic cable (90) which directs the emission to a remotely located multi-channel spectrometer detector.

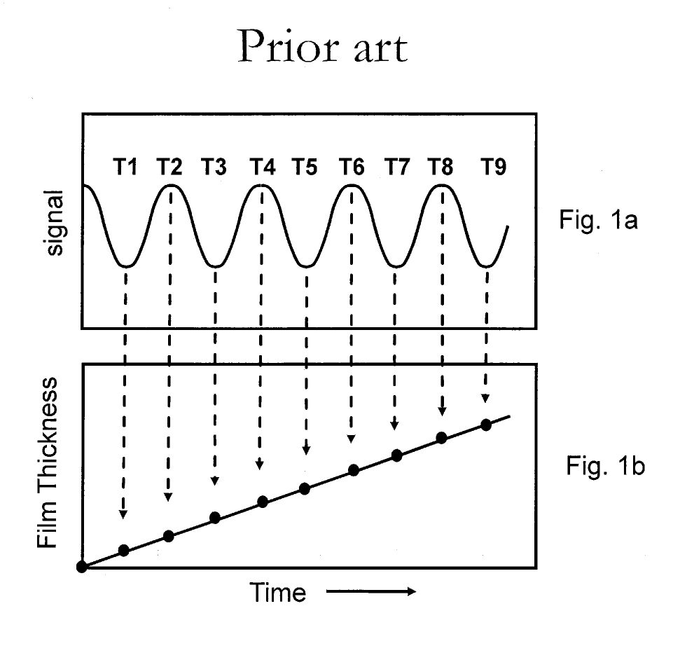

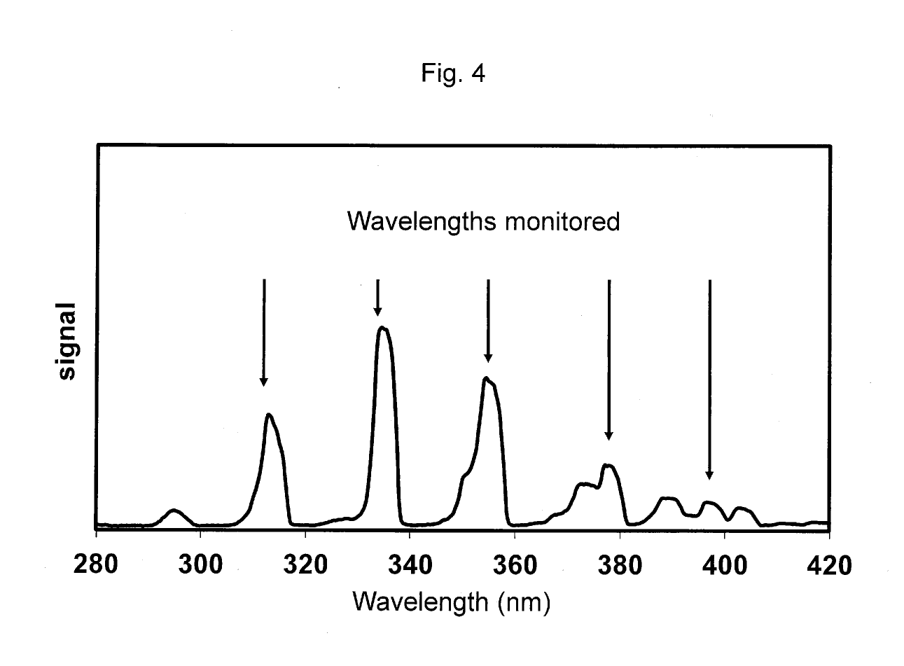

During the deposition of dielectric films such as silicon dioxide and silicon nitride, Nitrogen is commonly present within the plasma, either as a constituent of one of the reactive gases (e.g., NH₃ or N₂O), or as molecular Nitrogen used as a carrier gas. The emission of molecular Nitrogen is thus a major constituent of the spectrum emitted from such a deposition plasma as is shown in FIG. 4 in the 290 nm to 420 nm wavelength region. If Nitrogen is not present in the deposition process, then tracer gases (such as Nitrogen, Argon or Helium) may be purposely added to the process in order to increase the amount of plasma emitted radiation. A tracer gas can be any gas added to the process gas mixture to provide additional plasma emission wavelengths or enhancing the intensity of existing emission wavelengths without significantly shifting the plasma process performance. In a preferred embodiment, the tracer gas will add plasma emission wavelengths in the spectral region below 400 nm. When the reflected Nitrogen emission at 337 nm, for example, is monitored versus time as a 400 nm thick silicon nitride film is deposited, then a cyclical interference signal as shown in FIG. 1a is generated. The thickness change for one cycle for this film (refractive index of 2.0) is known from EQUATION 1 and is 84.25 nm. Using the prior art (FIG. 1a), the times, T1 to T9 of each interference maximum and minimum is noted and a graph of film thickness versus time is plotted (FIG. 1b). By extrapolation of this graph the process can be terminated when the target thickness of 400 nm is reached.

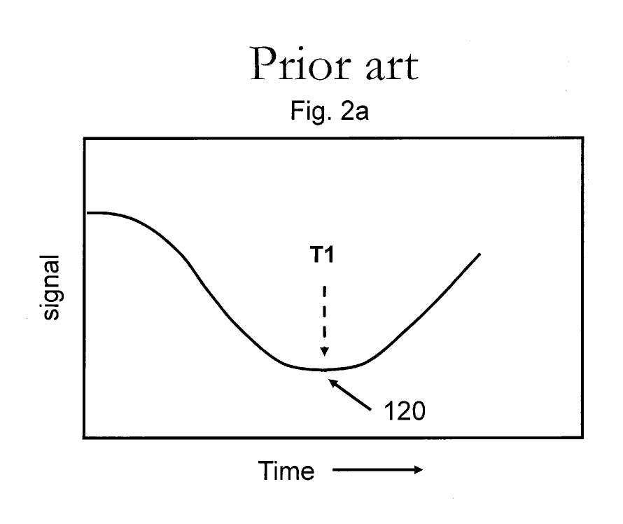

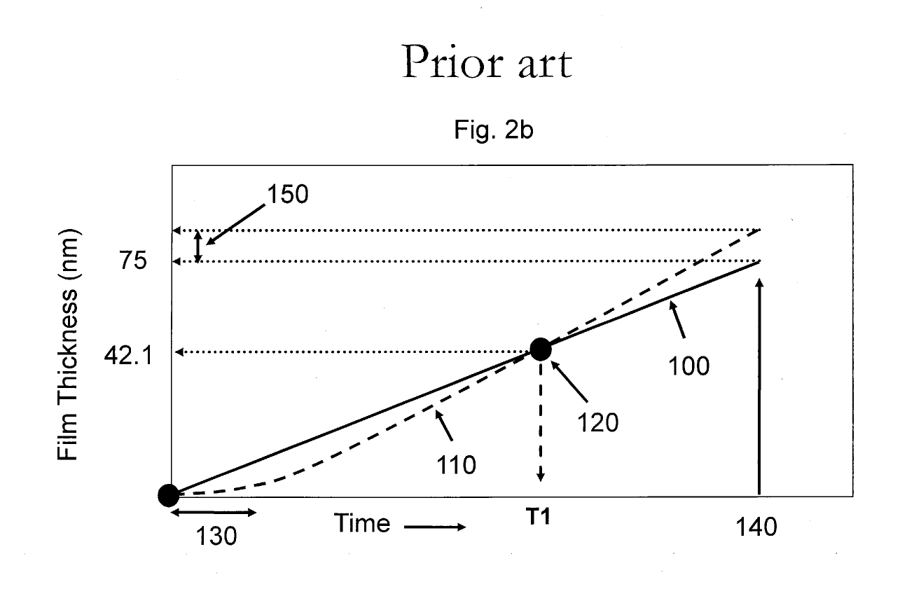

When a thinner film, for example 75 nm, is deposited, the interference signal observed at 337 nm is as is shown in FIG. 2a, where only the first minimum in the signal (half of an interference cycle) can be measured at time T1. If the film thickness versus time is plotted, as in the previous example, then a graph as shown in FIG. 2b is obtained. The point 120, at time T1, corresponds to a film thickness of 42.1 nm and line 100 represents the estimate of the film thickness versus time assuming that the film thickness is zero when the process time is zero. By extrapolating forward, the process is terminated at time 140, when a film thickness of 75 nm is predicted. In practice, the thickness of the film versus time may depart significantly from the linear relationship shown by line 100. It is not uncommon for there to be little deposition for a period of time 130, at the start of the process as the plasma stabilizes, so that the actual thickness versus time of the film is better represented by the dashed curve 110. This curve will still pass through the point 120, but has a different gradient (i.e., indicating a different deposition rate) than that of line 100. As a result, when the process is terminated at time 140, there is an error 150, in the final film thickness. The present invention overcomes this problem as detailed below.

Using the apparatus as shown in FIG. 3 or using an arrangement appropriate to the particular deposition equipment used, the reflected plasma emission is measured using a multi-channel detector or a number of discrete detectors, such that multiple wavelengths are measured simultaneously. When Nitrogen is present in the deposition process, it is advantageous to measure at wavelengths which coincide with the emission wavelengths of molecular Nitrogen since such measurements will result in the most intense signal and a high S/N (signal to noise) ratio. The Nitrogen emission does not occur at single wavelengths, but rather over a narrow band of wavelengths (for example the 337 nm emission is spread over the range 334 nm to 338 nm). When a multi-channel spectrometer is used, further enhancement in the S/N ratio is obtained by monitoring the output of a number of detector elements over which the emission is spread and then averaging these values. Such pixel averaging techniques used to improve S/N are well known to those skilled in the art. Using a spectrometer such as the USB2000 fitted with a 600 grooves/mm grating (as is manufactured by Ocean Optics Inc.), the output of approximately 12 detector elements can be averaged at each Nitrogen emission band.

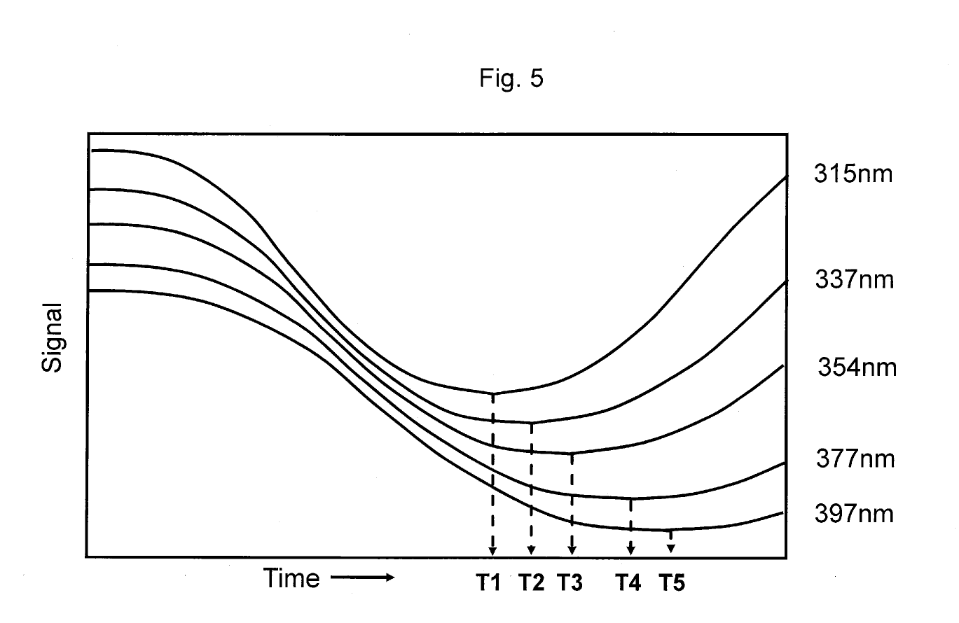

The output of the detector at the multiple selected wavelengths (in this instance the Nitrogen emission bands at 315 nm, 337 nm, 354 nm, 377 nm and 397 nm) during the deposition of a 50 nm silicon nitride film is as shown in FIG. 5. For the sake of clarity, the output at the different wavelengths has been normalized and separated along the vertical axis. The output at each wavelength passes through a minimum value at times T1-T5 respectively at which point the film thickness has a value corresponding to ½ interference cycle. The film thickness at each of these times can be calculated from EQUATION 2 knowing the wavelength and the refractive index of the film at that wavelength. EQUATION 2:

d=λ/4*n_{f}

where: λ=wavelength at which reflectance is monitored

n_{f}=refractive index of film at this wavelength

Since this technique relies on the optical properties of the film, the film thickness measurement accuracy depends critically on the accuracy with which the refractive index of the film is known. It is important that the refractive index is known at the measurement wavelength and hence so called “book values” for refractive index cannot be used since these are typically values obtained at longer wavelengths e.g., at the laser wavelength of 632.8 nm. At shorter wavelengths e.g., 300 nm to 400 nm, the refractive index does not have a constant value, typically increasing as the wavelength decreases. Also, the films deposited by PECVD are not stoichiometric and may contain other components, for example hydrogen, so that the film composition, and hence its optical properties, are peculiar to the deposition process and the deposition equipment used. Accurate values of the refractive index must therefore be determined for the particular deposited film.

Spectroscopic ellipsometry can be used to obtain the refractive index at different wavelengths, though care must be taken to ensure that the film thickness is within a range in which reliable refractive index measurements can be made. An alternative technique is to deposit a thick film, for example a film approximately 500 nm to 1000 nm thick, using the appropriate process and equipment, and monitor the reflectance at the selected wavelengths as noted previously. During this deposition process multiple interference cycles are generated, whose number, including fractional cycles, is counted. An accurate value for the film thickness is obtained, preferably using a non-optical technique such as AFM, SEM or profilometry. From the known values of film thickness, d, wavelength, λ, and number of interference cycles, N, it is possible to calculate an accurate value for the refractive index using EQUATION 3. EQUATION 3:

n_{f}=N·λ/2·d

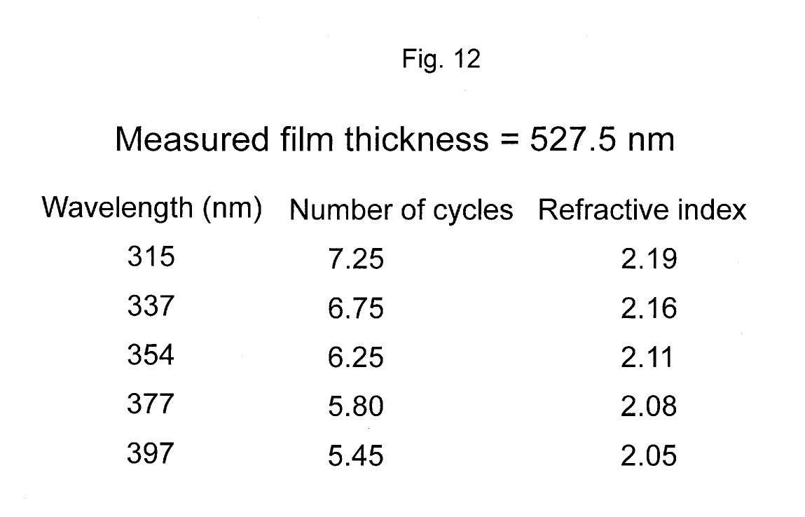

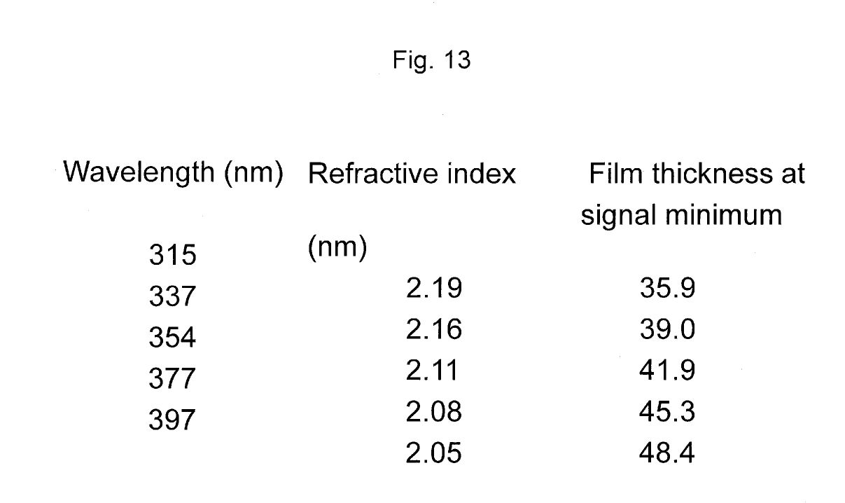

The values for the refractive index calculated for a silicon nitride film by depositing a 527.5 nm thick film are listed in the Table shown in FIG. 12. Using these values for the refractive index the film thickness at the first interference minimum at each wavelength can then be accurately calculated. These values are shown in the Table shown in FIG. 13.

The time at which there is a minimum value in the interference signal must also be determined with a high degree of accuracy in order to accurately control the process. A thin film with a thickness of <100 nm will typically be deposited in less than 100 seconds, possibly less than 50 seconds even when the process is adjusted to reduce the deposition rate. For very thin films (<50 nm) a process time of only a few tens of seconds may be typical. In order to accurately control the final thickness of such a film to within a few percent accuracy, termination of the process to within fractions of a second of the target time is required. Since the target time is calculated from measurements of the times of the reflectance minima, these measurements must also be made with fractional second accuracy.

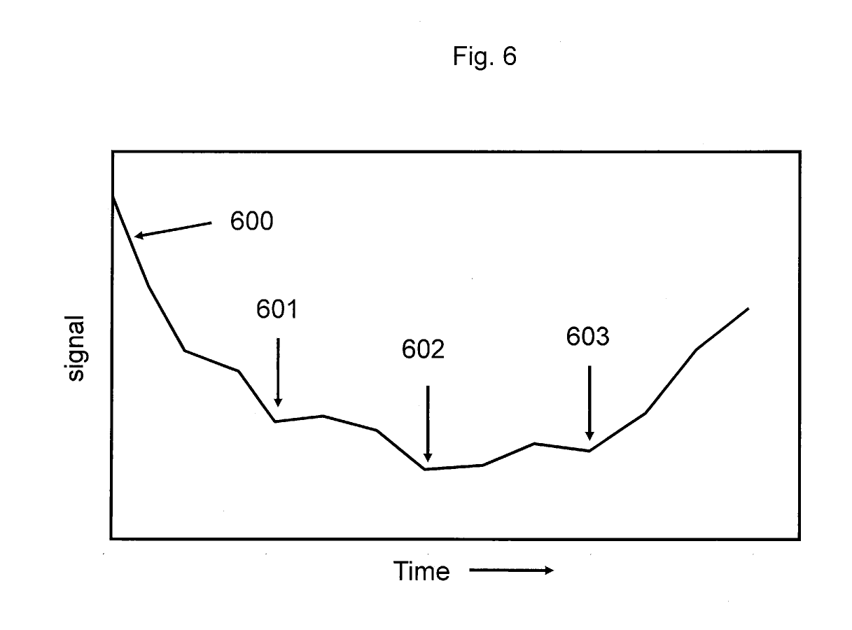

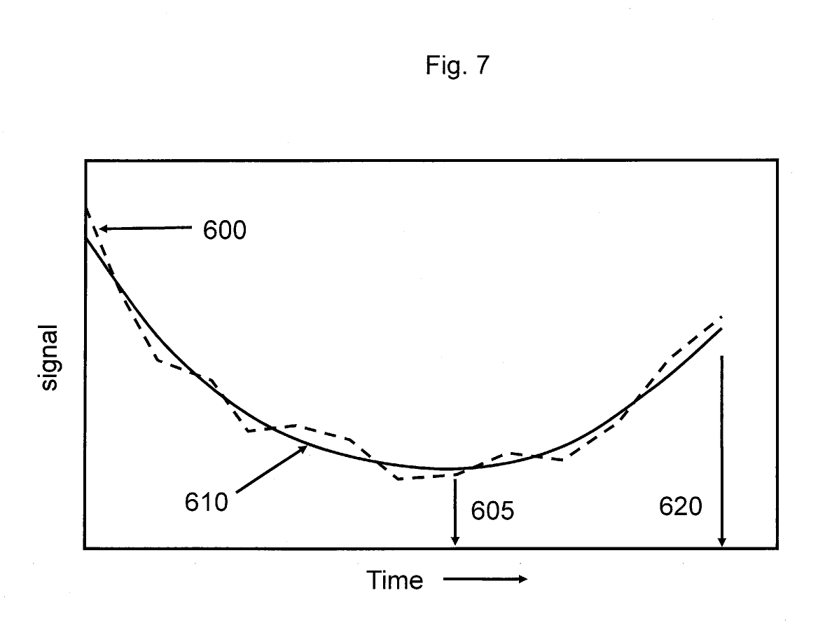

In FIG. 6, a typical output (600) from the detector as the interference signal passes through a minimum value is shown. Even though pixel averaging is applied to the signal there is still some noise on the signal which can produce false minima (601, 602, 603 for example). If the time for such values is used, then significant error is introduced into the process control method. The magnitude of the noise excursions can be reduced by signal averaging: however simple averaging such as a “running point average” cannot be applied since this is known to distort the signal and, in particular, shift the time of the minimum value by introducing a delay. Other, more sophisticated algorithms can be used to detect the true time of the minimum value in the presence of noise. For example, such an algorithm known to the inventors employs a statistical technique which performs a best fit of an equation, for example a second order polynomial equation, to the data points. Other equations including trigonometric functions, higher order polynomials, power functions, and combinations of these functions may also be employed. From this equation, the time of the minimum value is more accurately calculated, since the process of fitting to a number of data points effectively reduces the error. FIG. 7 shows a best fit curve (610) fitted to the raw data (600) and the time (605) of the minimum value calculated. Using such algorithms, the time of the minimum value is not known until after the minimum has occurred. It is important to use the calculated time for the minimum (605), not the time at which the calculation is performed (620). By appropriate selection of parameters, there need be only a small difference in these values: for example a minimum value occurring at 55.1 seconds is detected at 57 seconds.

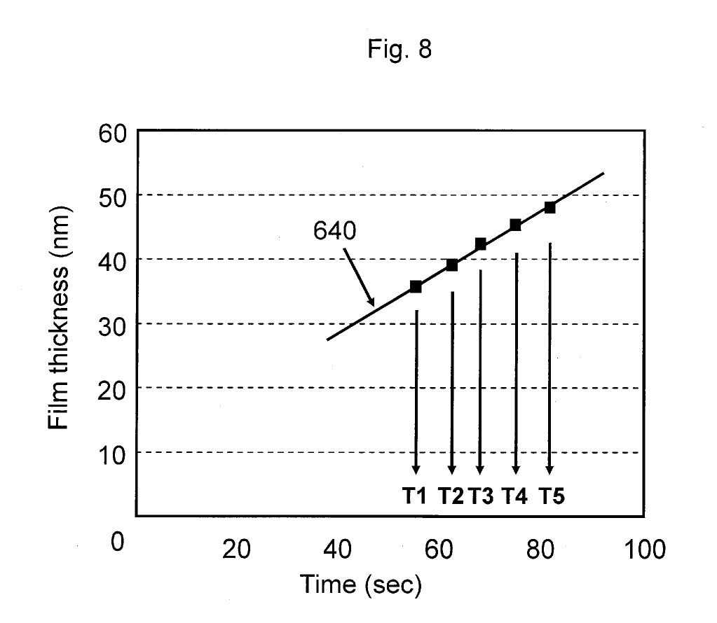

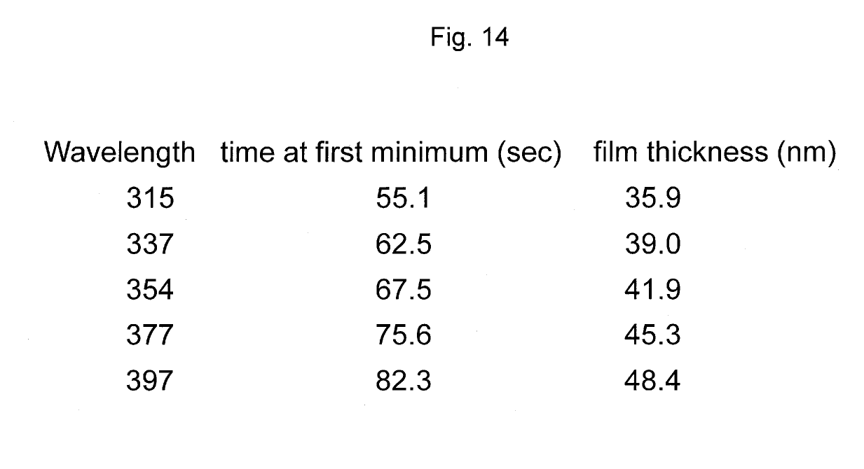

Using such a detection algorithm, the times calculated for the minima in the interference signals are shown in the Table shown in FIG. 14. From the data of the Table shown in FIG. 14, a graph of film thickness versus time can be constructed for illustrative purposes as is shown in FIG. 8. A mathematical analysis is performed using this data to derive an equation which provides an estimate of the film thickness versus time relationship (640). For example, as is well known in the art a regression analysis using either a linear or polynomial fit can be performed. Alternately, any other appropriate statistical method can be used to derive such an equation.

The mathematical analysis is performed each time a minimum value is detected at one of the monitored wavelengths, at which time an additional data point is added to the film thickness versus time data. Thus, the best fit equation is updated every time a minimum value is found. From this equation the process time, T_{end} at which the target thickness will be achieved is calculated, which time is also updated on each occasion that additional data is available. This time is compared with the current process time, and the process terminated when the process time is equal to T_{end}. At this time the film thickness is equal to the target thickness. Alternately, if additional processing is required, the process may be changed once the target thickness is attained, or a decision made to undertake other measures as appropriate.

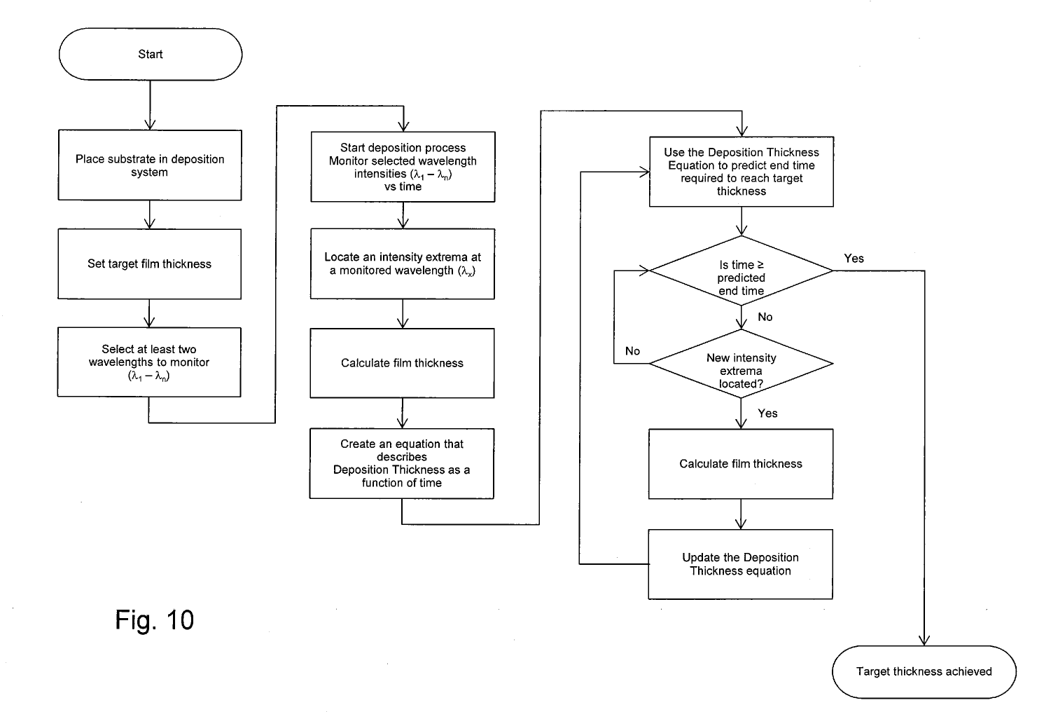

FIG. 10 shows a flow chart overview of one embodiment of the invention. This embodiment of the invention comprises the steps of: placing a substrate in a deposition system, setting a target thickness for the desired thin film deposition, selecting at least two wavelengths of light to monitor the deposited film growth, starting the deposition process and monitoring at least the selected wavelengths, locating an intensity extrema (e.g., maxima or minima) in a selected wavelength intensity, calculating a film thickness based on the located extrema, creating an equation that describes the deposition thickness as a function of time, using the created deposition thickness equation to predict a process time to reach the target film thickness, comparing the running process time against the predicted target thickness time. If the predicted target time has been reached, then the target thickness has been achieved. If the predicted target time has not yet been reached, the wavelength intensities are further monitored as the process continues. If a new intensity extrema is located prior to the process time reaching the predicted target thickness time, the deposition equation that describes deposition thickness as a function of time is updated and a new target thickness time is calculated based on the updated equation. The process time is again compared against the updated target thickness time. This process of monitoring time and updating the deposition thickness equation based on the location of new selected wavelength intensity extrema is repeated until the process time exceeds the predicted target thickness time to achieve the target deposition thickness. It is important to note that many variations of the described embodiment exist. For example, it is possible to set the target film thickness prior to placing the substrate in the deposition system. Similarly, the selection of the monitored wavelength may happen before of after the substrate is placed in the deposition chamber or the target film thickness is selected. In another embodiment, the monitored wavelengths are selected at the beginning of the deposition process. In the case where the wavelengths are selected at the beginning of the deposition process they are preferably selected within the first 10's of seconds of the process.

In another embodiment of the invention, the method may be beneficially applied to films with a non-constant composition. These non-constant films may be comprised of discrete layers or graded composition variation. In this case, the estimated refractive index will be for the composite film stack.

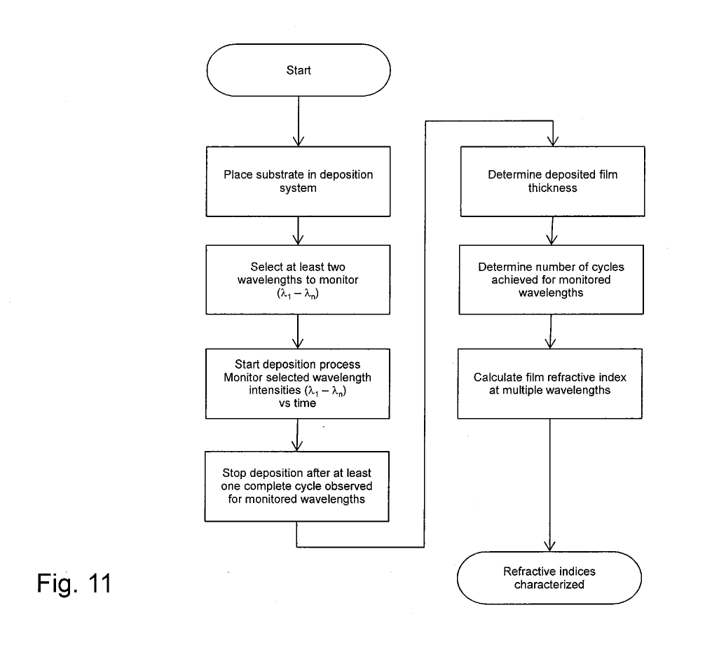

In order to convert the extrema of the monitored wavelength intensity or intensities into a film thickness, it is necessary to have an estimate of the deposited film's refractive index that corresponds to the monitored wavelength. FIG. 11 shows one method to obtain a refractive index estimate at a selected wavelength. In order to estimate the refractive index a test substrate is placed in the deposition system, at least one wavelength is selected to be monitored, the deposition process is started and the selected wavelength is monitored, the deposition process is continued until at least one complete cycle of the monitored wavelength is observed. Once the deposition process has been completed, the number of cycles (whole and fractional cycles) is estimated and the actual thickness of the deposited film is measured. Using the observed number of cycles and the actual film thickness, an estimate of the film's refractive index is calculated using Equation 3 for the selected wavelength. Please note that there are many variations of the described method to determine the film refractive index. For example, the selected wavelengths to be monitored can be determined after the substrate has been placed in the deposition system. Furthermore, it is possible to select the wavelengths after the process has been started.

In another embodiment of the invention, the method may be beneficially applied to films with a non-constant composition. These non-constant films may be comprised of discrete layers or graded composition variation. In this case, the estimated refractive index will be for the composite film stack.

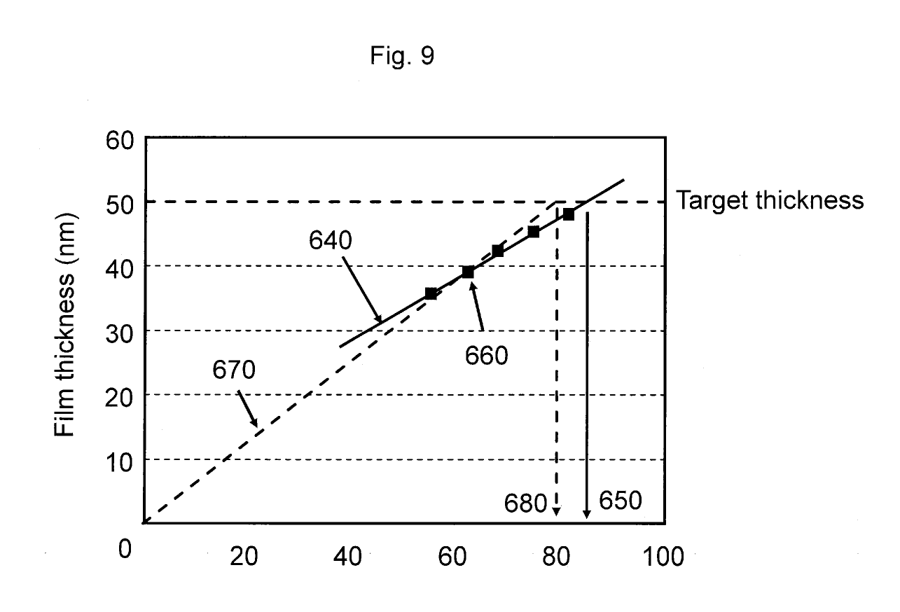

Using the present invention, with the example given, a process termination time of 85.8 seconds is calculated for a film thickness of 50 nm. This is shown in FIG. 9 (650). If prior art were used to calculate the process termination time, then significant error is present. For example, the first minimum at 337 nm occurs at 62.5 seconds, when the film thickness is 39.0 nm (660), from which values an apparent deposition rate of 0.624 nm/second is calculated. If deposition at this rate is extrapolated (670), then the estimated time for a film thickness of 50 nm is 80.1 seconds (680). This would result in too short a deposition process time and a film approximately 3.6 nm, or 7.2% less than the target value, which is an unacceptably high deviation.

Although the example of deposition described is for a thin film, monitoring the reflectance at multiple wavelengths can improve the thickness accuracy of thicker films since mathematical analysis using the additional data points obtained allows for a more accurate estimate of the film thickness versus time equation. When a film is thick enough to generate multiple interference cycles then both the maxima and the minima in the interference signal are used to generate such data. The signal maxima are detected in a similar manner to that described to detect a signal minimum.

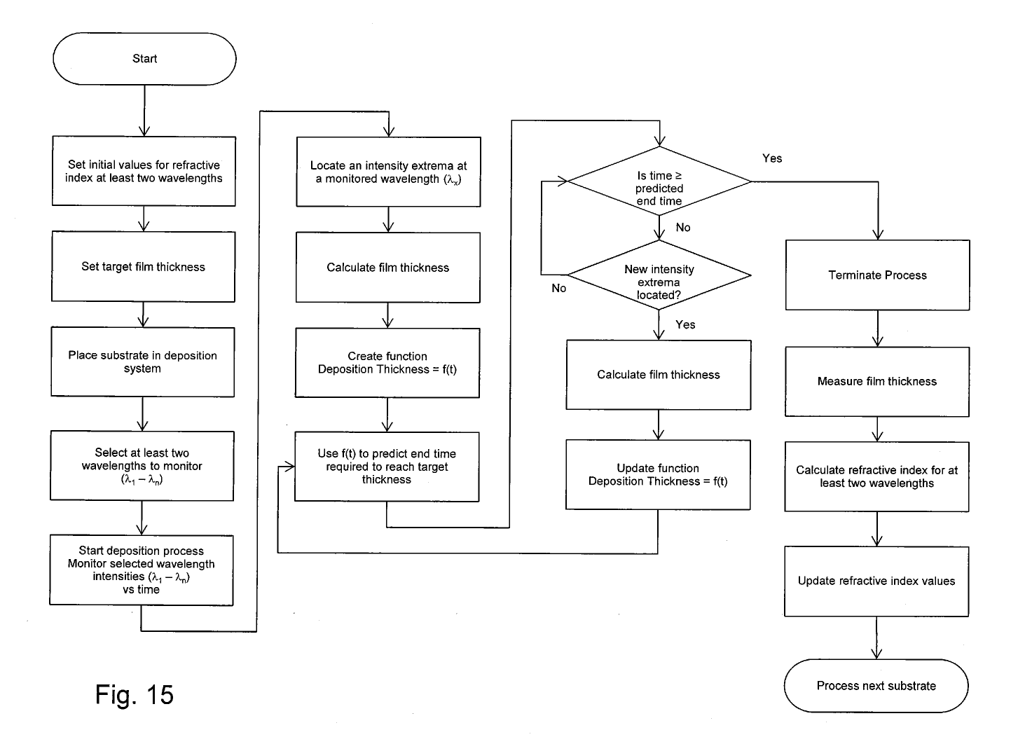

As shown in FIG. 15, a flow chart of the process comprises the steps of: setting initial values for refractive index using at least two wavelengths that will be monitored during the deposition of a thin film. A target film thickness is set for the deposition of the thin film. A substrate is placed within a deposition system. The thin film is deposited onto the substrate within the deposition system. The intensity versus time of reflected radiation at the two wavelengths having set initial values for refractive index are monitored during the deposition of the thin film. An intensity extrema is determined from at least one of the monitored wavelengths. A deposited film thickness is calculated using the intensity extrema determined from the monitored wavelength. A function for deposited film thickness versus time is created using the calculated film thickness. The function created for deposited film thickness is used to obtain an estimated time to achieve the target film thickness. If the time is greater than or equal to the predicted time then the deposition process can be terminated or changed. At that point, the film thickness is measured, the refractive index for at least two wavelengths is calculated, the refractive index values are updated, and the next substrate is placed in the deposition system for deposition of the thin film. If the time is less than the predicted time then a new intensity extrema is determined, the deposited film thickness is calculated using the new intensity extrema determined from the monitored wavelength, a new function for deposited film thickness is created using the new calculated film thickness, and the new function for deposited film thickness is used to obtain a new estimated time to achieve the target film thickness.

While the preceding examples have focused on deposition processes, the invention may also be beneficially applied to etching of thin films. Furthermore the invention may be applied to processes that consist of a combination of etch and deposition processes such as the DRIE process which is well known in the art.

The present disclosure includes that contained in the appended claims, as well as that of the foregoing description. Although this invention has been described in its preferred form with a certain degree of particularity, it is understood that the present disclosure of the preferred form has been made only by way of example and that numerous changes in the details of construction and the combination and arrangement of parts may be resorted to without departing from the spirit and scope of the invention.

Now that the invention has been described,

What is claimed is:

1. A method to determine the thickness of a thin film during deposition, said method comprising the steps of:
setting a target film thickness;
placing a substrate within a deposition system;
depositing the thin film onto the substrate within the deposition system;
monitoring radiation reflected from the substrate at multiple wavelengths during the deposition of the thin film;
monitoring a value derived from the reflected radiation;
detecting a time at which the derived value achieves a target value;
calculating a film thickness at the detected times to generate data;
performing a mathematical analysis on the generated data to determine an equation for deposited film thickness versus time; and
using the determined equation for deposited film thickness versus time to obtain an estimated time to achieve the target film thickness.

2. The method of claim 1 further comprising terminating the deposition of the thin film when the estimated time achieves the target film thickness.

3. The method of claim 1 further comprising changing the deposition of the thin film when the estimated time achieves the target film thickness.

4. The method of claim 1 wherein the target value is an extrema.

5. The method of claim 1 wherein the multiple wavelengths further comprising wavelengths between 290 nm to 420 nm.

6. The method of claim 1 wherein the multiple wavelengths further comprising wavelengths emitted by molecular Nitrogen.

7. The method of claim 1 wherein the mathematical analysis further comprising a regression analysis.

8. The method of claim 7 wherein the regression analysis further comprising a linear fit.

9. The method of claim 8 wherein the regression analysis further comprising a polynomial fit.

10. The method of claim 1 wherein the detecting step further comprising applying a statistical technique to detect a true time of the minimum value.

11. The method of claim 1 wherein the calculating step further comprising using a known wavelength and a pre-calculated refractive index of the thin film.

12. The method of claim 11 wherein the refractive index is pre-calculated from a thick film of the thin film.

13. A method to determine the thickness of a thin film during plasma deposition, said method comprising the steps of:
setting a target film thickness;
placing a substrate within a plasma deposition system;
introducing a reactive gas into the plasma deposition system;
igniting a plasma from the reactive gas within the plasma deposition system;
depositing the thin film from the ignited plasma onto the substrate within the plasma deposition system;
monitoring plasma emitted radiation reflected from the substrate at multiple wavelengths during the deposition of the thin film;
monitoring a value derived from the reflected plasma radiation;
detecting a time at which the derived value achieves a target value;
calculating a film thickness at the detected times to generate data;
performing a mathematical analysis on the generated data to determine an equation for deposited film thickness versus time; and
using the determined equation for deposited film thickness versus time to obtain an estimated time to achieve the target film thickness.

14. The method of claim 13 further comprising terminating the deposition of the thin film when the estimated time achieves the target film thickness.

15. The method of claim 13 further comprising changing the deposition of the thin film when the estimated time achieves the target film thickness.

16. The method of claim 13 wherein the plasma deposition of the thin film is terminated when the calculated equation film thickness equals the target film thickness.

17. The method of claim 13 wherein the plasma deposition of the thin film is changed when the calculated equation film thickness equals the target film thickness.

18. The method of claim 13 wherein the multiple wavelengths further comprising wavelengths between 290 nm to 420 nm.

19. The method of claim 13 wherein the multiple wavelengths further comprising wavelengths emitted by molecular Nitrogen.

20. The method of claim 13 wherein the mathematical analysis further comprising a regression analysis.

21. The method of claim 20 wherein the regression analysis further comprising a linear fit.

22. The method of claim 21 wherein the regression analysis further comprising a polynomial fit.

23. The method of claim 13 wherein the detecting step further comprising applying a statistical technique to detect a true time of the minimum value.

24. The method of claim 13 wherein the calculating step further comprising using a known wavelength and a pre-calculated refractive index of the thin film.

25. The method of claim 24 wherein the refractive index is pre-calculated from a thick film of the thin film.

26. A method to determine the thickness of a thin film during deposition, said method comprising the steps of:
setting initial values for refractive index using at least two wavelengths;
setting a target film thickness;
placing a substrate within a deposition system;
depositing the thin film onto the substrate within the deposition system;
monitoring intensity versus time at said two wavelengths during deposition of the thin film;
terminating the process when the target film thickness is achieved;
measuring the film thickness;
calculating the refractive index at the at least two wavelengths using the measured film thickness;
updating the initial values of refractive index for the at least two wavelengths; and
processing the next substrate using the updated initial values of refractive index for the at least two wavelengths.
